(19) United States
(12) Patent Application Publication
(10) Pub. No.: US 2010/0089448 A1
(43) Pub. Date: Apr. 15, 2010

(54) Coaxial Solar Cell Structure and Continuous Fabrication Method of its Linear Structure

(76) Inventor: Chun-Chu Yang, Kaohsiung City (TW)

Correspondence Address: FRENKEL & ASSOCIATES, 3975 UNIVERSITY DR., STE. 330, FAIRFAX, VA, 22030, US

(21) Appl. No.: 12/248,092

(22) Filed: Oct. 9, 2008

(51) Int. Cl. H01L 31/00; B05D 5/12

(52) U.S. Cl. 136/257; 427/74

(57) ABSTRACT

A coaxial solar cell forces an exposed annular light receiving layers of a constant thickness to directly receive projection of light excitedly to generate pairs of electrons and holes that are driven by radial built-in electronic field formed on a PN junction to travel by the same distance paths to coaxial inner and outer electrodes. The photons directly enter an exposed drift region. The excited pairs of electrons and holes are separated by the even built-in electronic field to output current. Loss caused by crowding and recombination of diffusion current can be prevented. Photoelectric conversion efficiency improves without losing photon energy of short wavelengths projecting to the surface. The linear coaxial solar cell is fabricated by forming coaxial and annular semiconductor layers or compound films through deposition. Thus, it can be continuously fabricated by extending its length and mass production to reduce costs.

### FIELD OF THE INVENTION

The present invention relates to a coaxial diode structure of solar cells to generate electric power and a continuous fabrication method of its linear coaxial solar cell structures.

### BACKGROUND OF THE INVENTION

Generating electric power through solar energy is a vital technology at present due to increasing shortage of energy resources, especially to countries relying on importation of energy resources. How to lower fabrication cost of solar cells and increase photovoltaic conversion efficiency have become critical success factors of promoting alternative energy resources in large scales.

The solar cell (also known as photovoltaic cell) can convert light radiation to electric energy through a commonly known photovoltaic effect. When photons of sun radiation hit an active region (such as a depletion region) of the solar cell, they are absorbed and pairs of electrons and holes are generated. These electrons and holes are separated from a built-in electronic field. For instance, a P-I-N solar cell made from hydrogenated amorphous silicon has a built-in electronic field formed in a P-type semiconductor layer, an I-type intrinsic semiconductor layer and a N-type semiconductor layer. The photons of desired wavelengths are absorbed by the I layer to generate pairs of electrons and holes. The electrons flow to an external electrode of the N-type semiconductor layer due to the built-in electronic field, while the holes flow to another external electrode of the P-semiconductor layer due to the built-in electronic field. Such flow of the electrons and holes form a photovoltage and a photocurrent of the solar cell. The holes drift in a direction same as the electronic field. Because of the action force of the built-in electronic field, the drift speed of the electrons and holes is much faster than the diffusion speed of electrons and holes generated outside the electronic field. Hence current generated by the electrons and holes at the diffusion speed is less desirable for output of photovoltaic current. The slower diffusion current flows outside the solar cell later than the drift current, or even vanished by recombination before being output. To boost the photovoltaic current through continuously impact of the photons to quickly accelerate energy accumulation and effectively release the energy, a general approach is to shrink the diffusion region and expand the drift region, such as interposing a thicker layer of an intrinsic semiconductor without any donor or acceptor between a P-type semiconductor and a N-type semiconductor to become a P-I-N solar cell diode as shown in FIG. 1. This is why a PIN principle is adopted. In the triple-layer structure of P-I-N, a depletion region appears close to two end contacts of the P-type semiconductor and N-type semiconductor. As the I-type semiconductor has a higher resistance, the electronic field at the two end contacts is expanded and distributed to the whole I-type semiconductor. Hence the entire I-type semiconductor is located in a higher electronic field as shown in the right side of the FIG. 1. The distribution of electronic field intensity generated by the electricity of the depletion region at two ends expands the drift region to cover almost the entire solar cell. As a result, most of the photons entered the I-type semiconductor are absorbed at a desired depth. Namely, the photovoltaic current is mostly formed by the drift current. Compared with PN solar cell, the PIN solar cell has a faster response speed in output and the solar cell efficiency (η) is higher.

On the other hand, the diffusion current, for electron and hole carriers generated in a doped N or P layer by photons hitting, is temporarily generated without the action of electronic field due to being located outside the electronic field. The current speed is slower and the recombination lifetime is too short to be separated and generate heat. Hence it not only does not deliver output current, but continuously generates heat and results in a higher temperature and a lower efficiency. As a result, the photon energy hitting the outmost P-layer of the P-I-N solar cell or the inmost N-layer of the N-I-P solar cell loses the chance of converting to electric energy. This phenomenon is affected by the photon amount of each wavelength of the solar spectrum and the depth of the selected semiconductor material penetrable by the photons of each wavelength.

The amount of solar energy convertible to electric energy can be known from the solar spectrum distribution chart shown in FIG. 2 which indicates the relationship of the solar energy intensity and the wavelength of the solar spectrum. AMO shows energy distribution in the outer space, namely outside the atmospheric layer. The amount of air passed through by the sunlight is called AIR MASS (shown by AM, m). As air is absent the outer space, it is set by the zenith and shown by AMO. m=Sec θ. θ is the zenith angle of the sun, and θ=0° and Sec 0°=1. Hence the measured value of the zenith is AM1 on the ground. However, factored in the latitude, the sunlight is usually obtained at an elevated angle of 30 degrees relative to the zenith. Thus there is a AM2 curve distribution (Sec 30°=2). Through integration of the light spectrum of the full wavelength distribution, the AMO total energy amount is 135.3 mW/cm², while AM2 is about 72-75 mW/cm².

Based on the relationship of energy and wavelength, the energy is maximum at wavelength 0.7 μm, namely the amount of photons is greatest at such a wavelength, as indicated by the relationship of photon density and wavelength shown in FIG. 3. While the principle and technique of generating photovoltaic current by breaking the bandgap of semiconductor material through photons and energy thereof of each wavelength are well developed and adopted, there is still no material available to date that can absorb all the wavelengths of a full spectrum and convert to electric energy. Moreover, there are differences in absorption coefficient for different wavelengths on solar cell materials. The differences make many issues unraveled, such as how deep the photons have to penetrate and how much current can be generated. All these make fabrication of the solar cells more complicated. Refer FIG. 4 for the relationship of various material absorption coefficient and penetration depth and wavelength. It shows an example based on silicon absorption coefficient distribution. The silicon has a bandgap Eg=0.67 eV. Among the solar energy absorbed by silicon, the maximum wavelength is called cutoff wavelength λ_{c}=h_{c}/ΔE □ 1.2398/ΔE(eV)=1.13 μm, namely for solar cells made from silicon, the penetrate photons which are greater than the one with wavelengths set forth above cannot be absorbed and converted to electric energy.

Similarly, the cutoff wavelength for Ge is 1.85 μm, and for GaAs is 1.65 μm. Thus the spectrum energy of the solar cells made from Ge above 1.85 μm cannot be absorbed and is wasted. On penetration depth, for solar cells made from silicon, the thickness has to be greater than 100 μm to absorb the solar energy at the wavelength of 1.0 μm. The thickness of 100 μm means the location depth of depletion layer or space charge region where pairs of electrons and holes can be generated, namely, adding the width of the depletion layer and the thickness of the N-semiconductor (the photons first enter the surface layer or enter from a lower side of a P-type semiconductor). For using in the outer space, as getting electric power is more difficult, full spectrum absorption has to be considered. For instance, a very small thickness for short wavelengths and a greater thickness for long wavelengths should be included to increase conversion of photovoltaic current from all entering photons. However, the absorption location of the short wavelengths is on the surface where diffusion current of the solar cells is generated that is not convertible. To achieve absorption at a greater depth for the long wavelengths the thickness of the material has to be increased. This increases the fuel cost of thrusting into the outer space. Hence many factors have to be considered and weighed in selecting the material for solar cells. The solar cells with full spectrum absorption usually are fabricated by stacking multiple layers of different materials. For instance, a first layer is made from thin silicon; next, another layer is added to allow the cutoff wavelength to pass through, such as a Ge layer formed at a thickness between 1 μm and 10 μm that also has absorption capability; then a third layer made from InGaAs at a thickness between 1 μm and 100 μm is added. Thus a total thickness of 300 μm is formed to enhance effectiveness.

The conventional techniques for fabricating semiconductor solar cells and organic semiconductor solar cells generally include stacking layers of required materials on a planar substrate by flatting deposition, adding epitaxy, evaporation or diffusion printing or the like. The bottom layer and top layer are collector electrodes. Projected sunlight is converged and collected in a built-in electronic field formed on a PN junction of the electric generating active region. Pairs of electrons and holes are excited, and charges are accumulated and separation is formed to be output. In the conventional solar cell structure previously discussed, the opaque collector electrode at the top layer occupies the optimal photoelectric input and conversion location, and blocks a lot of sunlight. In order to prevent current from accumulating on the collecting conductor close to the current output end and resulting in voltage drop due to increasing conductor resistance, the area of the conductor close to the current output end usually is enlarged gradually. As a result, the area to receive sunlight decreases. This reduces electric generation effectiveness and wastes input power. To overcome the aforesaid light masking problem of the collector electrode, a technique of adopting a transparent electrode has been developed to increase input of solar energy. But the material for total transparent electrode still is not yet available to date. In addition, the electricity generating cell made by stacking layers in an up and down fashion adopted in the conventional techniques has the PN junction formed originally to drive the built-in electronic field, the active electronic field for the donor (or acceptor) to generate ionization is initially distributed evenly. After having received continuous sunlight projection, due to uneven electrode layout (such as various types of grid electrodes) of physical conductive wires on the upper and lower layers to collect electric output, uneven currents are delivered. This affects the original even distribution of the built-in electronic field on the PN junction and results in uneven electronic field distribution. And different moving distances in the drift region are formed. As a result, different drift velocity (Vn) and different electron mobility (μn), and different hole mobility also occur. Because of the uneven electronic field the generated charges collide and cause energy waste, coupling with gradual recombination of the charges, electricity generating efficiency drops. Referring to FIG. 6, pairs of electrons and holes generated by light projection in a weak electronic field do not produce a desirable drift output current. The lower mobility of electrons and holes often incurs recombination and results in loss.

Furthermore, during light transmission in the semiconductor the energy of photons attenuates according to the traveling depth. This can be depicted by the an absorption coefficients (cm⁻¹). The number of photons Np(x) of a wavelength λ penetrating into a depth x of a semiconductor can be described according the equation as follow:

Np(x)=Np(0) exp(−α(λ)x) (1)

where Np(0) is the number of photons entered the surface of the semiconductor. The relationship of the absorption coefficient and semiconductor material used on solar cells and the wavelength λ of entering photons shown in FIG. 4 can indicate the depth of semiconductor entered by the photons at various wavelengths. For instance, the absorption coefficient is α=10⁴ cm⁻¹ for sunlight of a wavelength of 0.5 μm in silicon. It means that pairs of electrons and holes are generated when the light of wavelength of 0.5 μm entered at the depth of 1 μm is absorbed. The wavelength of 0.5 μm has the greatest energy in the sunlight spectrum (with greatest number of photons for the sunlight projecting to the ground surface at such a wavelength). Based on FIG. 3, FIG. 4 shows the depth of solar cell penetrated by the photons of various wavelengths. To allow light of 0.5 μm to enter the electric generating PN junction at a depth of 1 μm, the distance between the surface of the incident light and the PN junction that generates pairs of electrons and holes is smaller than 1 μm. It is too thin, and the first N layer has to be made very thin to sufficiently direct the solar energy of the sunlight wavelength of 0.5 μm to reach the PN junction to generate most electric power. This is one of the reasons why the first entering N layer or P layer of the conventional solar cell has to be made relatively thin. Because of this, lights of shorter wavelengths cannot be collected and converted to electric power.

Another factor causing the higher cost of the conventional solar cell is the cost of fabricating the chip set substrate. The substrate usually is formed by slicing a high cost ingot to become substrate wafers. Such a process causes a lot of material waste. To make mass production of the solar cells at a lower cost, the aforesaid conventional fabrication process has to be changed.

### SUMMARY OF THE INVENTION

In view of the shortcomings of the traditional techniques to fabricate the conventional solar cell, namely:

1. The conventional solar cell made by stacking deposition or epitaxy in an upper and lower layer fashion has asymmetrical electrodes and results in a lower electric generation efficiency.

2. The conventional solar cell made by stacking deposition or epitaxy in an upper and lower layer fashion cannot fully absorb the photons of shorter wavelengths that penetrate in a smaller thickness, and energy conversion cannot be performed as desired, and waste of the photon energy of the short wavelengths occurs.

3. The electrodes of the collector electrodes at the upper and lower layers occupy light entrances and create the drawback of light masking.

4. Slicing the ingot to form wafers of the substrates creates a great loss of pure and expensive raw material of the solar cells, and results in a higher cost of the solar cells and makes promotion and extensive applications of the solar cells more difficult.

The present invention aims to provide a coaxial solar cell structure by incorporating the structural principle of the coaxial semiconductor light detector disclosed in Applicant's previous (PRC/Taiwan) patent application No. 095146963 entitled “COAXIAL LIGHT GUIDE OPTICAL FIBER WITH REFRACTIVE INDEX DISTRIBUTED ON RADIUS AND COAXIAL LIGHT GUIDE SYSTEM EQUIPPED WITH A COAXIAL SEMICONDUCTOR LIGHT SOURCE AND A COAXIAL LIGHT DETECTOR” to overcome the aforesaid problems.

The coaxial semiconductor light detector has a positive electrode and a negative electrode that are coaxial and spaced from each other at a constant distance to supply electric power to a light detecting annular semiconductor layer coaxially located in the middle. It also detects or collects output current alterations (or amplification). The invention—coaxial solar cell adopts its coaxial electrode output to converge current through a built-in electronic field to resolve the aforesaid problems according the following two methods:

1. The coaxial solar cells is coaxially structured as shown in FIG. 7 to make the upper and lower layer arrangement of the conventional solar cell electrodes to become a coaxial arrangement. Multiple layers(tandem) with a coaxial structure can be made to form a common core of the solar cell that can stacked on the same axis to become a string and form a full spectrum coaxial solar cell (called FSCSC in short hereinafter) as shown in FIG. 8. The FSCSC has a common core electrode and each peripheral annular electrode connecting to each other. It can be coupled in series to boost voltage, or coupled in parallel to augment current. Various types high efficient and planar electric power supply apparatus can be formed.

2. The coaxial solar cell structure can be made in a linear fashion of a greater unit area and arranged in a juxtaposed manner to supply electric power at an economic scale and a lower cost to replace the conventional solar cell consisting of small pieces of planar substrates. There is no need to slice the expensive ingot to fabricate the substrates. Thus the cost can be reduced.

The invention is further elaborated as follow:

1. The coaxial solar cells is coaxially structured as shown in FIG. 7 to make the upper and lower layer arrangement of the conventional solar cell electrodes to become coaxial. The light exciting active layer, namely the depletion region is no longer hidden beneath the bottom layer in a planar fashion, but in a coaxial and annular fashion. Take a coaxial solar cell formed in a PIN structure as an example, it has a coaxial core electrode 701, a N-type annular semiconductor layer 702, an I-type annular semiconductor layer 703, a P-type annular semiconductor layer 704, a coaxial peripheral annular electrode output end 705, an insulation dielectric layer 706 and a core power supply electrode output end 707. The annular depletion region is exposed to the surface to directly receive light. Thus even the photons of the shortest wavelength can be instantly absorbed. Pairs of electrons and holes excited by the light accelerate in the built-in electronic field of the drift region and rapidly move to become current output. The short wavelength can quickly produce output. Thus it can overcome the second problem mentioned above. Similarly, the photon energy of the rest wavelength regions can be absorbed by desired stacking layers at selected thickness according to the bandgap of different materials and penetrable depth. FIG. 8 illustrates such an example which has a short wavelength coaxial solar cell layer 801, a medium spectrum coaxial solar cell layer 802 and a long wavelength coaxial solar cell 803 and a common core 804 that are overlapped and coupled in series to form a full spectrum coaxial solar cell assembly.

The coaxial solar cell of the invention has an annular PN junction of a constant thickness that can be ionized to generate an electronic field spaced at a constant distance in the positive and negative radial direction as shown in FIG. 9. Pairs of electrons and holes are generated upon direct projection of the photons which are driven by the built-in radial electronic field formed on the PN interface and drifted to an inner electrode and an outer electrode of each coaxial layer by the shortest path of the same distance. The region constantly receives impact of the photons and rapidly accumulates a great number of electrons and holes at higher potentials like a battery replenished with electric power, thus can supply electric power to the exterior. Therefore the coaxial solar cell of the invention not only can absorb and convert the photons of short wavelengths, also can supply more saturated electric power to overcome the first problem mentioned above. The top view of the drawing also shows an inner electrode and an outer electrode that are coaxial. In terms of the drift region to generate most electric power in each unit of FSCSC, the power supply electrode does not occupy the entering path of the photons. In terms of the light receiving region of the total FSCSC, only the coaxial peripheral annular electrode occupies the entering spots of the photons, but at a small light detection ratio. Thus there is no masking loss and absorption loss in the effective drift region. As a result, the coaxial solar cell structure of the invention can resolve the third problem set forth above.

2. The invention also provides another coaxial solar cell structure that is made in a linear fashion and coupled in serial and parallel manner to replace the conventional planar solar cell formed on a hard substrate to supply electric power in serial and parallel manner. Thus there is no need to fabricate the solar cell by using the expensive substrate material. And the fourth problem of high cost mentioned above also can be overcome. As the conventional technique has to slice the ingot to wafers to produce the solar cells, a great amount of waste occurs to the expensive pure material in such a slicing process. Thus results in a higher cost of the raw material of the solar cells and hinders promotion and extensive applications of the solar cells. Although polycrystalline or multi-crystalline silicon material has been developed in recent years to substitute the planer fabrication process, and the drawback of high cost to produce the solar cells by slicing the ingot to form substrate wafers not longer exists, it still is a planar fabrication processes that involves uniform vaporizing plating, epitaxy forming or depositing semiconductors in a limited area. To produce the solar cell at a greater size is not possible through such an approach. Hence a greater area has to be provided to collect solar energy radiated from a great distance away. As a result, the conventional solar cell has to be arranged in serial and parallel by small pieces to form a planar solar cell to become a greater size to collect solar energy and supply electric power for larger power supply equipments. Such a serial and parallel arrangement aims to increase current and voltage, and often makes the structure more complicated, and causes a lot of waste in common area and space. This also makes the cost higher and creates interface compound resistance, and consumes the converted electric power.

The technique of fabricating optical fibers has been established for years. It can be adopted to fabricate the coaxial solar cells to form a linear structure through thin film deposition techniques such as MOCVD or PCVD by using organic semiconductor materials or inorganic semiconductor material such as amorphous silicon or polycrystalline silicon. As a surface consists of lines connecting to one another continuously, and a curved surface consists of curved lines connecting to one another continuously, the solar cells made in coaxial lines, either straight lines or a curved surface consisting of linear lines can be assembled to form a power supply equipment of a great area. The cost is lower and a single sheet of a great size can be formed to output electric power economically. Such a technique can contribute to the welfare of human being and alleviate the hazards of global warming created by decades of operations in petrochemical industries and electrical power conversion.

Refer to FIG. 11 for an embodiment 2 of the invention. It provides another electric power supply equipment of a great area consisting of linear coaxial solar cells. One thousand coaxial solar cells each at a length of one meter are coupled in parallel. To further lower the cost, the invention provides a continuous fabrication method of the linear coaxial solar cell structure that can produce in large quantity economically, as shown in an embodiment 3.

In short, the invention repositions the electrodes of electric power supply of the coaxial solar cells to overcome the problems of the conventional solar cells. It aims to achieve the following objects:

1. Improve electric generation efficiency of the coaxial solar cells, and achieve more saturation of electric power of the coaxial power storage structure. It also directly absorbs photons of incident short wavelengths, or provides a coaxial shared structure with multiple layers of different materials in different absorption coefficient and bandgap to form a FSCSC full spectrum coaxial solar cell structure. Thus a more comprehensive solar cell electric power supply can be formed.

2. No hindrance of electrode lines at the inlet. Light inlet can be made at a greater size to increase efficiency.

3. A great planar surface or curved surface can be formed by coupling the linear coaxial solar cells to replace the conventional technique that adopts small pieces in a complicated structure and consumes electric power and more space and materials. Fabrication can be rationalized and mass production can be accomplished to realize economic benefits. It helps to spawn new industries and improves the wellbeing of mankind.

The foregoing, as well as additional objects, features and advantages of the invention will be more readily apparent from the following detailed description, which proceeds with reference to the accompanying drawings. The embodiments discussed below serve only for illustrative purpose and are not the limitations of the invention. It is to be noted that the drawings aim to illustrate the features and characteristics of the invention, and the dimensions or quantity of the elements are made to facilitate discussion without strictly taking in account of absolute size.

### BRIEF DESCRIPTION OF THE DRAWINGS

FIG. 1 is a schematic view of a conventional PIN solar cell structure and the built-in electronic field.

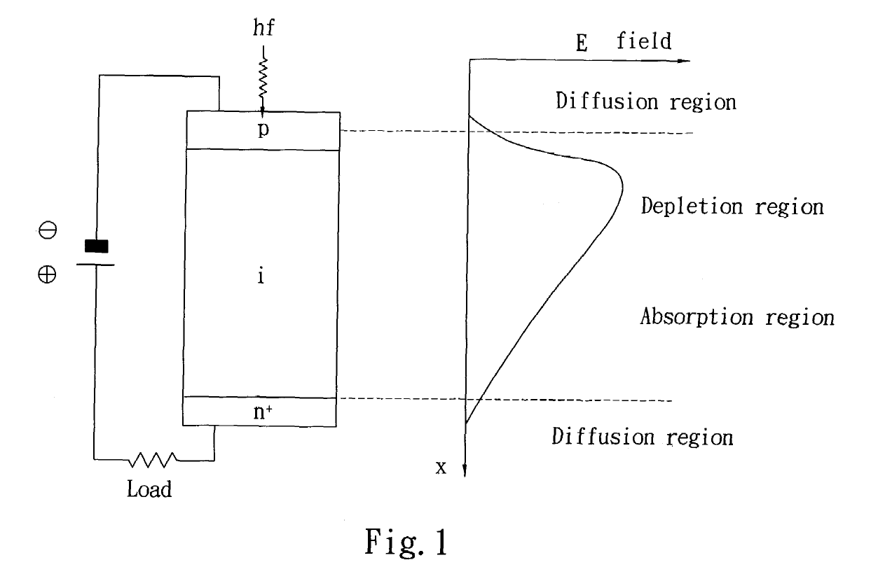

FIG. 2 is a chart showing the relationship of solar energy intensity and sunlight spectrum wavelengths.

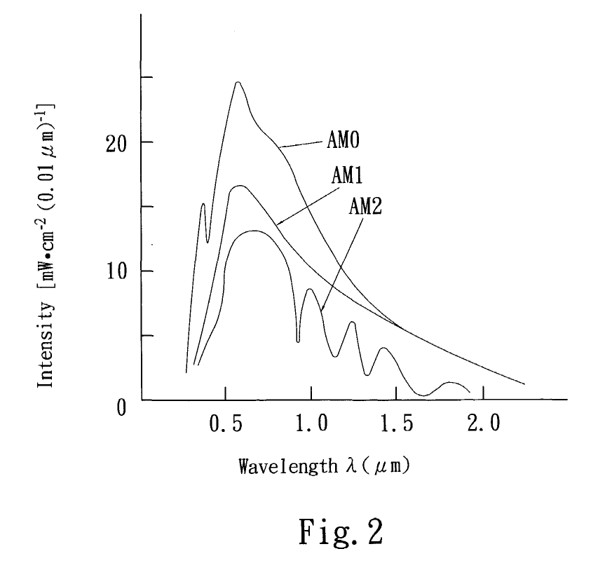

FIG. 3 is a chart showing the relationship of solar photon density and sunlight spectrum wavelengths.

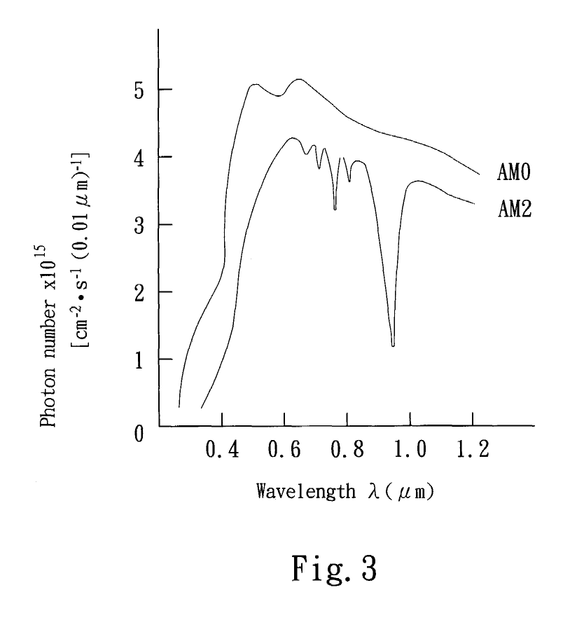

FIG. 4 is a chart showing the relationship of absorption coefficient of various types of materials and penetration depth and wavelengths.

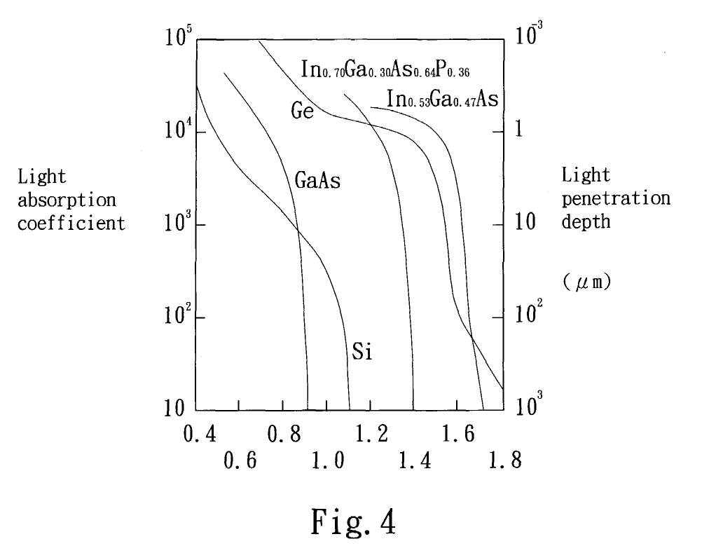

FIG. 5 is a schematic view of an example of a conventional collector conductor hindering incident light.

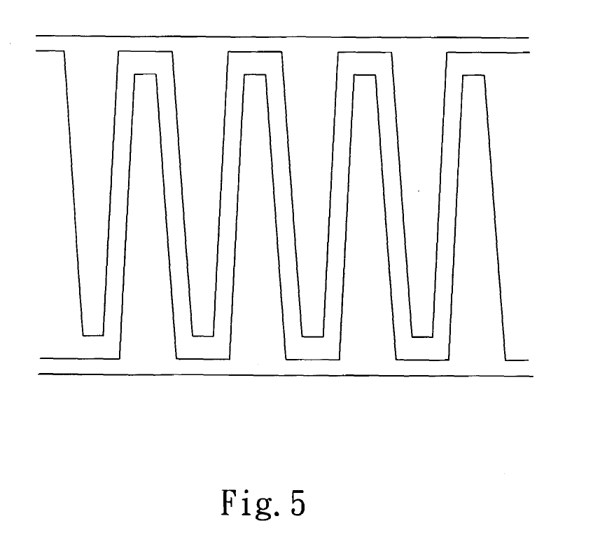

FIG. 6 is a schematic view of a conventional solar cell with an upper and lower collector electrodes that form variations of built-in electronic field and flow directions of drift current.

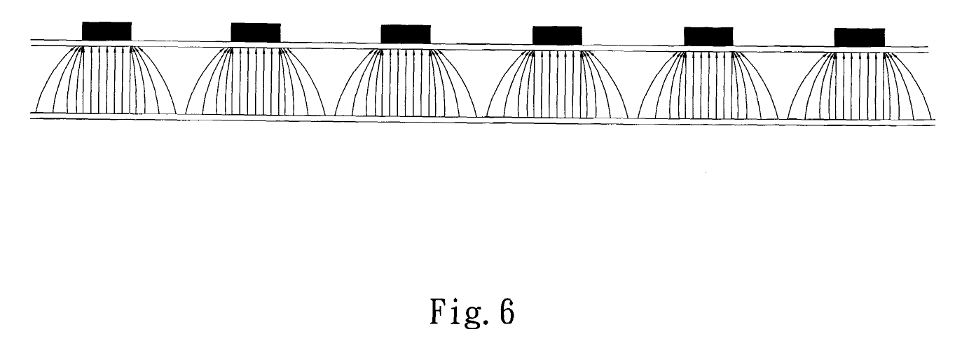

FIG. 7 is a perspective view of a PIN coaxial solar cell, partly cut off.

FIG. 8 is a perspective view of a full spectrum coaxial solar cell, partly cut off.

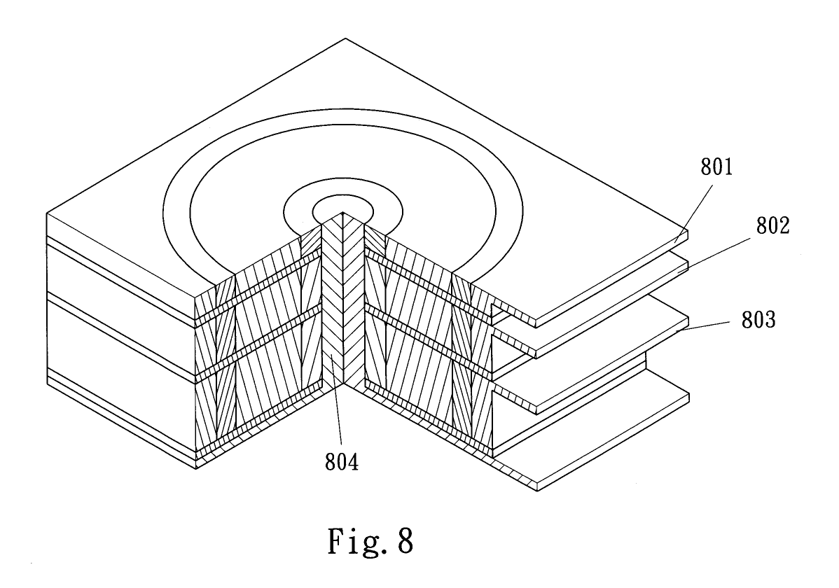

FIG. 9 is a schematic top view of a coaxial solar cell with a radial built-in electronic field distributed on a PN junction.

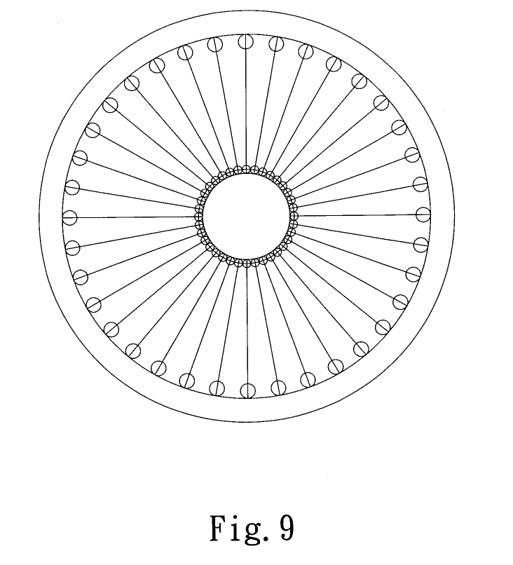

FIG. 10 is a schematic view of embodiment 1 of an electric power supply consisting of coaxial solar cells.

FIG. 11 is a schematic view of embodiment 2 of an electric power supply consisting of linear coaxial solar cells.

FIG. 12 is a schematic top view of embodiment 2 of an electric power supply consisting of linear coaxial solar cells showing photons entering paths.

FIG. 13 is a schematic view of embodiment 3 of the continuous fabrication method of linear coaxial solar cells.

FIG. 14 is a schematic view of embodiment 3 of the continuous fabrication method of linear coaxial solar cells to form ribbon-type solar cells.

### DETAILED DESCRIPTION OF THE PREFERRED EMBODIMENTS

### Embodiment 1

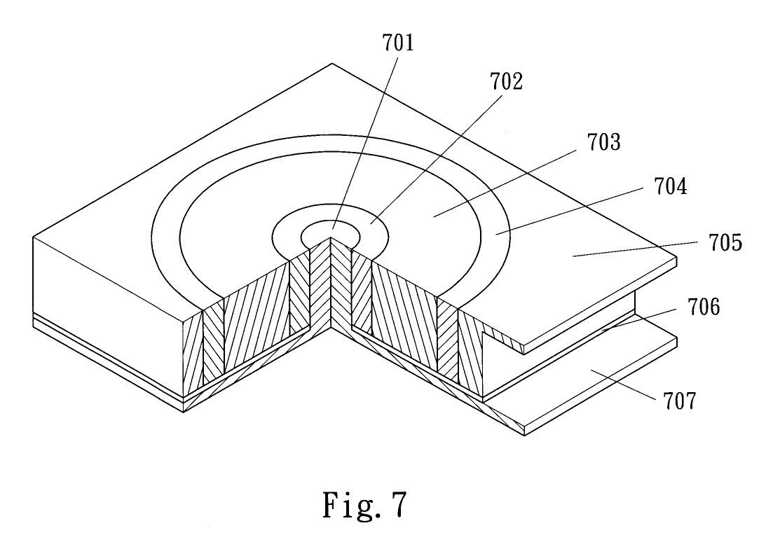

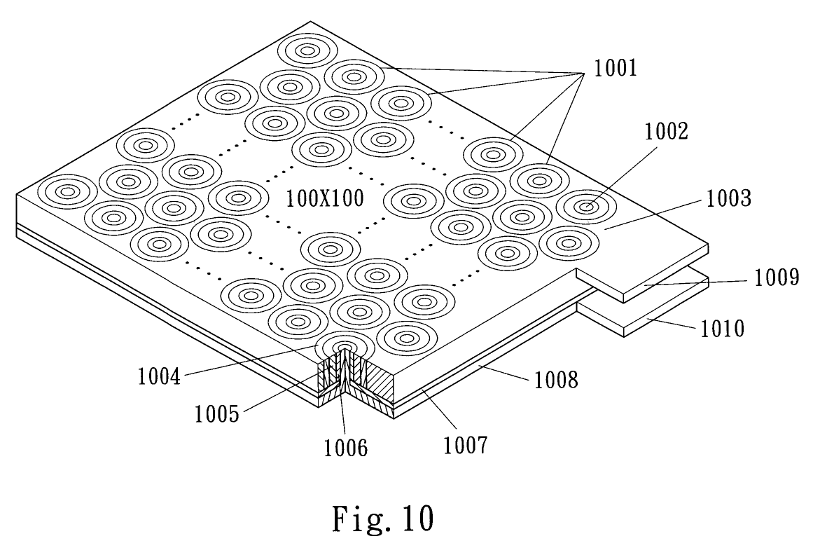

A solar cell power supply equipment consisting of coaxial solar cells arranged in a mesh layout as shown in FIG. 10. It has 100 rows of silicon P-I-N coaxial solar cells 1001 (referring to FIG. 7 for the structure). Each row has 100 coaxial solar cells 1001. Each coaxial solar cell 1001 has a power supply core electrode 1002. A common collector cathode 1003 is provided on the periphery for all the coaxial solar cells with a shared output terminal 1009 for the collector cathode. Each solar cell has a P-type annular semiconductor layer 1004, an I-type annular intrinsic semiconductor layer 1005, a N-type annular semiconductor layer 1006. There is also a planar insulation dielectric layer 1007 and a common anode plane 1008 to connect the bottom of the core electrode 1002 with a planar anode output terminal 1010 formed thereon.

Based on the electric power generation principle of the coaxial solar cell previously discussed, the photons of various wavelengths directly project to the drift region. The excited electrons and holes at different depths are driven at the same time at the same distance by the built-in radial electronic field evenly distributed on the PN junction, thus separation occurs to generate flowing out of current. And the power supply battery set with total 10000 coaxial solar cells coupled in parallel to deliver current is formed. Such a battery set can also be coupled in a serial or parallel fashion according to minimum and maximum required voltage and current of usage to achieve desired power supply.

While FIG. 10 depicts the power supply consisting of the coaxial solar cells that adopts the shared core design, other types of shared core designs also can be adopted according to requirements of different applications.

The power supply equipment consisting of the coaxial solar cells discussed in embodiment 1 not only can absorb and convert photon energy of the short wavelength spectrum in the shallow layer to electric power that is not possible in the conventional solar cells, a fabrication process to form a greater thickness to absorb photons of longer wavelengths also can be established. Aside from forming a top layer on the first layer at a depth for cutoff wavelength, the invention also allows stacking a second or third layer with material capable of absorbing and converting bandgap to form a coaxial solar cell assembly capable of absorbing light in full spectrum.

### Embodiment 2

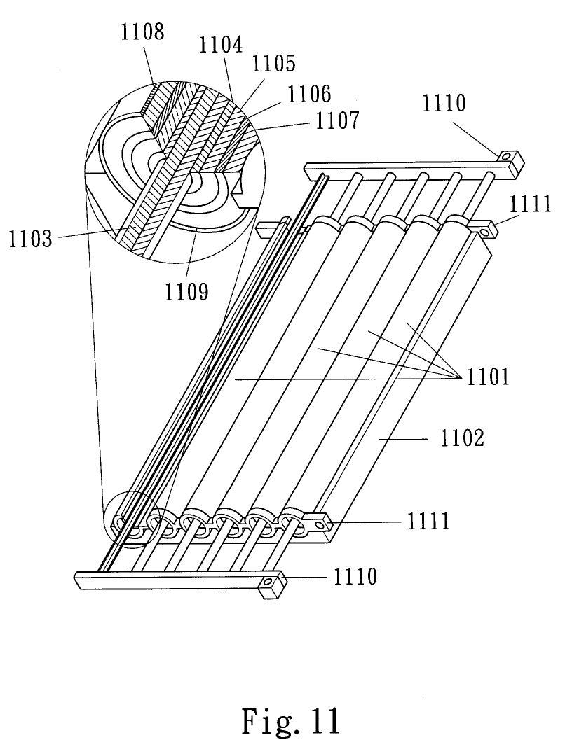

Refer to FIG. 11 for a second embodiment of the invention. It is a power supply equipment of a large unit area consisting of linear coaxial solar cells. It has 1000 linear coaxial solar cells 1101 (each at a length of 1 meter) coupled in parallel and laid on a same plane or a selected curved surface, such as an anchor seat 1102 of a streamline body surface of an air plane or vehicle. The power supply equipment thus formed can be coupled in a serial or parallel fashion according to minimum and maximum required voltage and current of usage to achieve power supply goals.

In the embodiment 2, each linear coaxial solar cell 1101 is formed by coaxial materials, including a reflective metal core anode 1103, a tubular N-type semiconductor layer 1104, a tubular I-type semiconductor layer 1105, a tubular P-type semiconductor layer 1106, a transparent tubular peripheral annular electrode conductive layer 1107, a surface protection layer 1108 plated with anti-reflection film on an outer side, and a reflective plated layer 1109 coated on the interface of the anchor seat. The linear coaxial anode 1103 is coupled in parallel to form a positive output terminal 1110. The peripheral annular cathode 1107 is coupled in parallel to form a negative output terminal 1111.

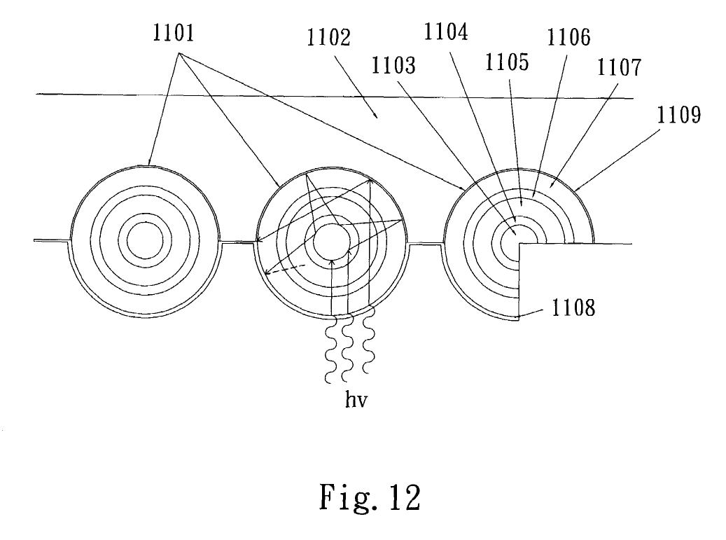

The linear coaxial solar cell also has high performance in energy collection. With the coaxial and even built-in electronic field as previously discussed, the photons entered sideward generate pairs of excited electrons and holes that can be separated and accumulated to supply electric power required. Although it does not have an exposed drift region and some of the short wavelength solar energy is lost, a larger lateral side area is provided to function like a spherical lens on the coaxial solar cell. According to material characteristics, desired reflection and refraction can be arranged to get a light absorption path from shorter to longer wavelengths. Such a structure can make the coaxial solar cell at a smaller diameter and lighter to absorb a wider spectrum to compensate the loss of the shorter wavelengths as shown in FIG. 12.

As previously discussed on embodiment 2, the power supply equipment consisting of the linear coaxial solar cells not only can be formed with a smaller diameter of the linear coaxial solar cell, also can absorb photon energy of a wider spectrum. It also can be arranged in a plane or a desired curved surface of a greater unit area to suit power supply requirements of any application environments and match other factors, such as profile, angular arrangement, serial and parallel assemblies, power supply assemblies, terrain conditions and latitude conditions and the like. There is no need to include the expensive fabrication process of slicing the ingot to form wafers of substrates. A larger area solar cell power supply equipment can be made at a lower cost to expand applications and benefit users.

### Embodiment 3

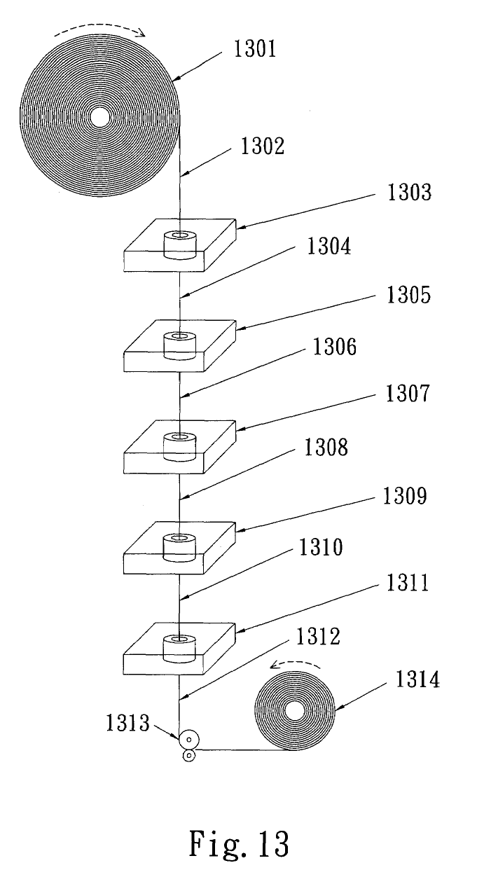

Refer to FIG. 13 for the continuous fabrication method of the linear coaxial solar cells used in embodiment 2 shown in FIG. 11. As the linear coaxial solar cell is fabricated by depositing layers of coaxial annular semiconductors or thin films of compounds, a conventional continuous drawing and coating process to form linear optical fibers can be adopted. First, a core conductor 1302 such as a stainless fine wire is drawn out from a feeding roll 1301; by passing through an annular N-type semiconductor layer depositing apparatus 1303 a first coaxial structure 1304 plated with N-layer is formed; through an annular I-type semiconductor layer depositing apparatus 1305 a bi-layer coaxial structure 1306 plated with the N-layer and I-layer is formed; through an annular P-type semiconductor layer depositing apparatus 1307 a triple-layer coaxial structure 1308 plated with N-layer, I-layer and P-layer is formed; through an annular electrode conductor depositing apparatus 1309 a tetra-layer coaxial structure 1310 coated with N-layer, I-layer, P-layer and a transparent electrode conductive layer is formed; finally, through an annular anti-reflection layer or protection layer depositing apparatus 1311 a penta-layer coaxial linear structure 1312 coated with N-layer, I-layer, P-layer, transparent conductive layer and anti-reflection layer is formed. Then the coated linear structure passes through a rotary axle 1313 equipped with a speed feedback control and is continuously wound by a winding apparatus 1314 to finish the fabrication process.

The annular depositing apparatus to fabricate the linear coaxial solar cells previously discussed have many choices and combinations depending on different factors and requirements, such as depositing films by sputtering, film types such as CIGS or varying depositing thickness according to dye-sensitive solar cell DSSC, required epitaxy forming conditions, and the like. The linear coaxial solar cells thus formed can be arranged to make various types of power supply products.

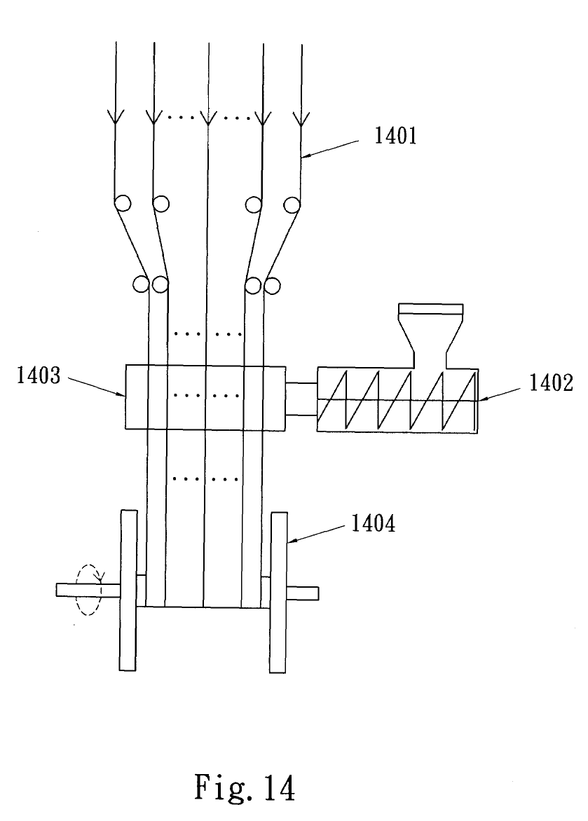

The linear coaxial solar cell may also be arranged in a ribbon-type to form a pliable and large area power supply equipment. Refer to FIG. 14 for making ribbon-type solar cells based on the linear coaxial solar cell depicted in FIG. 13. A plurality of linear coaxial solar cells 1401 are pulled out in a juxtaposed manner; through an extruder or a large area ribbon fabrication apparatus 1402 a ribbon-type head 1403 can be formed and jacketed; finally the linear ribbon coaxial solar cells are wound by a winding apparatus 1404.

It is to be noted that the coaxial solar cell power supply system previously discussed may be formed by each element according to functions required, or in combinations of two or more elements according to applications and requirements.

Although the preferred embodiments of the invention have been illustrated as coaxial solar cell structure and continuous fabrication method of its linear structure but not be limited the invention within the enclosed drawings, every application and alterant structure under the spirit and scope of the invention will be treated as the invention.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A coaxial solar cell structure, comprising an inner core conductor and an outer conductor formed coaxially on a planer or a semiconductor substrate to supply electric power, the inner core conductor and the outer conductor being interposed by a plurality of coaxial and annular semiconductor layers or compound layers that continuously receive projection of sunlight photons to accumulate and convert to electric energy, the structure further having an anode and a cathode that are coaxial to output the electric power and an annular light receiving region to directly receive photon energy of the sun and a built-in electronic field evenly distributed radially to excite and separate pairs of electrons and holes to form a drift current or deliver electric power, wherein the inner and outer conductors are electrodes to supply the electric power and are coaxial with the annular semiconductor layers or the compound layers that perform photovoltaic conversion.

2. A coaxial solar cell structure having a plurality of overlapping layers to selectively absorb wavelengths to form a multi-layer and coaxial solar cell power supply structure to absorb energy of photons radiated from the sun, comprising:
a coaxial solar cell of claim 1 for wavelengths penetrable to a small depth; or a coaxial solar cell of claim 1 for wavelengths penetrable to a medium depth; or
a coaxial solar cell of claim 1 for wavelengths penetrable to a great depth; or
a coaxial solar cell of claim 1 made from materials having a selected bandgap; and
a common core structure which couples cores of the power supply structure or both power supply and light conduction in an upright overlapping fashion according to the penetrable depth of each wavelength and has each coaxial peripheral electrode to output the electric power for selected applications.

3. A linear coaxial solar cell structure formed by extending the axial length of the coaxial solar cell structure of claim 1, wherein the coaxial solar cell is formed in a linear and elongate fashion to receive photons of the sun sideward to supply the electric power.

4. A coaxial solar cell electric power supply having a large unit area formed on a plane or a curved surface comprising the coaxial solar cell structure of claim 1, wherein the electric power apparatus of the coaxial solar cell is coupled in parallel plane or coupled in curved surface to deliver a parallel-output, a serial output or the output of serial-and-parallel.

5. A coaxial solar cell electric power supply having a large unit area formed on a plane or a curved surface comprising the coaxial solar cell structure of claim 2, wherein the electric power apparatus of the coaxial solar cell is coupled in parallel or coupled in curved surface to deliver a parallel-output, a serial-output or the output of serial-and-parallel.

6. A coaxial solar cell electric power supply having a large unit area formed on a plane or a curved surface comprising the coaxial solar cell structure of claim 3, wherein the electric power apparatus of the coaxial solar cell is coupled in parallel or coupled in curved surface to deliver a parallel-output, a serial output or the output of serial-and-parallel.

7. A continuous fabrication method to produce linear coaxial solar cells through a depositing apparatus or a coating apparatus, comprising:
forming the linear coaxial solar cell in an upright and juxtaposed fashion; or forming the linear coaxial solar cell in a horizontal and juxtaposed fashion; or forming a portion of the linear coaxial solar cell in an upright and juxtaposed fashion and other portion of the linear coaxial solar cell in a horizontal and juxtaposed fashion;
running a conductive core electrode of the linear coaxial solar cells through the center of a selected equipment to continuously deposit by layers and produce linear coaxial solar cells ; wherein each of the linear coaxial solar cells has coaxial annular semiconductor layers or compound conductive layers and a conductive layer that are formed by continuous deposition in an axial and extended fashion from an inner annular layer to a outer peripheral layer.
